(19) United States
(12) Patent Application Publication
(10) Pub. No.: US 2006/0244115 A1
(43) Pub. Date: Nov. 2, 2006

(54) Chip package structure and method for manufacturing the same

(75) Inventors: Chien Liu, Kaohsiung City (TW); Meng-Jen Wang, Ping Tung City (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/313,679

(22) Filed: Dec. 22, 2005

(30) Foreign Application Priority Data
Apr. 28, 2005 (TW) 94113730

(51) Int. Cl. H01L 23/02

(52) U.S. Cl. 257/678

(57) ABSTRACT

A chip package structure and a method for manufacturing the same are disclosed. The chip package structure comprises a carrier and a chip deposed on the carrier. The carrier comprises a heat-sinking pad, a plurality of pins, and at least two supporting bars, in which the heat-sinking pad has a carrying surface. The chip includes a plurality of bonding bumps flipped and connected to the heat-sinking pad, the pins, and the supporting bars of the carrier.

### RELATED APPLICATIONS

The present application is based on, and claims priority from, Taiwan Application Serial Number 94113730, filed Apr. 28, 2005, the disclosure of which is hereby incorporated by reference herein in its entirety.

### FIELD OF THE INVENTION

The present invention relates to a chip package structure and a method for manufacturing the same, and more particularly, to a quad flat no-lead (QFN) package structure and a method for manufacturing the same.

### BACKGROUND OF THE INVENTION

For increasing the integration of integrated circuits and demand for high performance electronic products, packaging techniques are driving toward increasing the package density, decreasing the package size and reducing the transmission distance to accommodate the micro-miniaturization of integrated circuit devices and the increasing number of input/output (I/O) pins.

Package structures of integrated circuit devices are of various types, among which providing a lead frame is a common one, wherein the lead frame includes a chip pad and a plurality of pins deposed around the chip pad. Then, a chip is adhered to the chip pad and pins by bonding bumps deposed on the chip. Subsequently, an encapsulant material is used to cover the chip, the chip pad and a portion of each pin to fill up the space between the chip and the chip pad, so as to complete the packaging of the chip. After packaging, the chip can be electrically connected to external devices by the bonding pad and the pins.

FIG. 1 illustrates a top view of a conventional lead frame. A lead frame 100 is mainly composed of a chip pad 106, a plurality of pins 102 and a connection frame 108, wherein the connection frame 108 typically surrounds the chip pad 106 and the pins. One of two ends of the pins 102 surround the chip pad 106, and the other end of the pins 106 extend and are connected to the connection frame 108. In some package structures, the chip pad 106 also has a heat-sinking function, so that the chip pad 106 may be referred to a heat-sinking pad. In order to support the chip pad 106, the lead frame 100 further includes four supporting bars 104 extending inward from four corners of the connection frame 108 of the lead frame 100 and connecting with the chip pad 106 for supporting the chip pad 106.

However, the supporting bars 104 occupy the space of the four corners of the lead frame 100, so that the pins 102 cannot be deposed at the four corners of the lead frame 100, thereby wasting the space of the lead frame 100 and limiting the design of the lead frame 100.

### SUMMARY OF THE INVENTION

Therefore, one objective of the present invention is to provide a chip package structure, in which supporting bars of a heat-sinking pad of the lead frame can be used as pins, such that the space of the lead frame can be effectively utilized.

Another objective of the present invention is to provide a method for manufacturing a chip package structure, which uses pins of the lead frame as supporting bars, thereby freeing the design limitation of the lead frame to facilitate the design of the lead frame.

According to the aforementioned objectives, the present invention provides a chip package structure, comprising a carrier and a chip deposed on the carrier. The carrier comprises a heat-sinking pad having a carrying surface, a plurality of pins and at least two supporting bars. The chip comprises a plurality of bonding bumps and is flipped and connected to the heat-sinking pad, the pins and the supporting bars of the carrier.

According to a preferred embodiment of the present invention, the chip package structure is a quad flat no-lead package structure. The bonding bumps include a plurality of ground bumps and a plurality of supply bumps, and the supporting bars are electrically connected to the ground bumps and/or the supply bumps. According to another preferred embodiment of the present invention, the supporting bars are separated from the heat-sinking pad, the bonding bumps include a plurality of signal bonding bumps, and the supporting bars are electrically to the signal bonding bumps.

According to the aforementioned objectives, the present invention provides a lead frame, comprising: a heat-sinking pad having a carrying surface for carrying a chip; a plurality of pins; and at least two supporting bars for supporting the heat-sinking pad, wherein the supporting bars are suitable for electrically connecting the chip and are located at regions outside of corner regions of the lead frame.

According to a preferred embodiment of the present invention, a surface of the chip comprises a plurality of bonding bumps deposed thereon, a carrying surface of the heat-sinking pad is connected with a part of the bonding bumps, and all of the pins are respectively connected with another part of the bonding bumps, wherein the bonding bumps include a plurality of ground bumps and a plurality of supply bumps, and the supporting bars are electrically connected to the ground bumps and/or the supply bumps.

According to the aforementioned objectives, the present invention also provides a method for manufacturing a chip package structure, comprising the following steps. A lead frame is provided, wherein the lead frame comprises a heat-sinking pad having a carrying surface, a plurality of pins and at least two supporting bars connecting to the heat-sinking pad. A chip is provided, wherein a surface of the chip comprises a plurality of bonding bumps deposed thereon. The chip is connected to the lead frame, wherein the chip is electrically connected to the heat-sinking pad, the pins, and the supporting bars by the bonding bumps.

According to a preferred embodiment of the present invention, the heat-sinking pad has a heat-sink surface opposite to the carrying surface, each of the supporting bars includes a connection part connected to a side of the heat-sinking pad, and a lower surface of the connection part is contiguous to the heat-sinking surface. After the step of providing the chip, the method for manufacturing a chip package structure further comprises providing an encapsulant to cover the chip and fill up the space between the chip, the heat-sinking pad, and the pins; and the heat-sinking surface of the heat-sinking pad is exposed by the encapsulant. A surface of the connection part of each supporting bar connecting to the heat-sinking surface is exposed by the encapsulant, and after the step of providing the encapsulant, the method for manufacturing a chip package structure further comprises performing a separation step to disconnect the supporting bars and the heat-sinking pad.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 illustrates a top view of a conventional lead frame;

FIG. 2 illustrates a top view of a lead frame in accordance with a preferred embodiment of the present invention;

FIG. 3 illustrates a cross-sectional view of a chip package structure in accordance with a preferred embodiment of the present invention; and

FIG. 4 illustrates a cross-sectional view of a chip package structure in accordance with another preferred embodiment of the present invention.

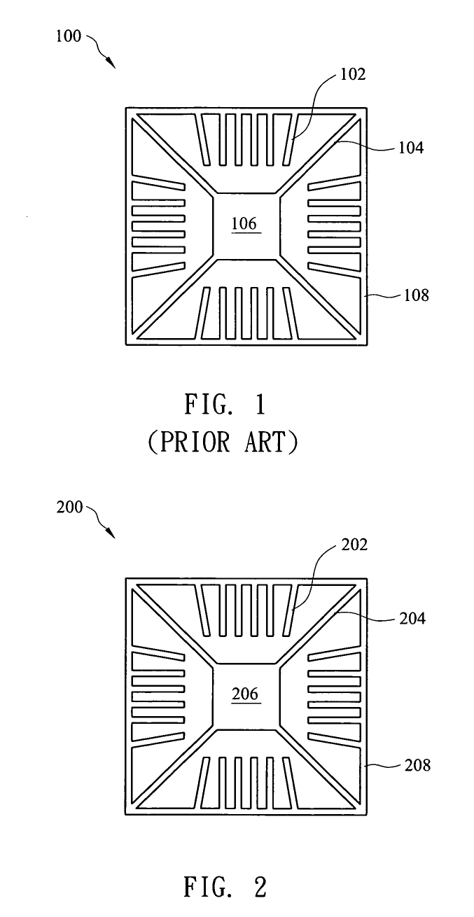

### DETAILED DESCRIPTION OF THE PREFERRED EMBODIMENT

The present invention discloses a chip package structure and a method for manufacturing the same, wherein the chip package structure is a quad flat no-lead package structure. In order to make the illustration of the present invention more explicit and complete, the following description is stated with reference to FIGS. 2 through 4.

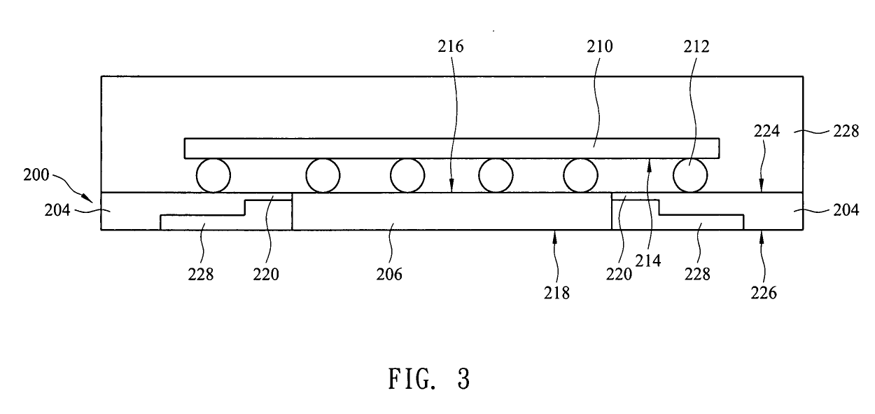

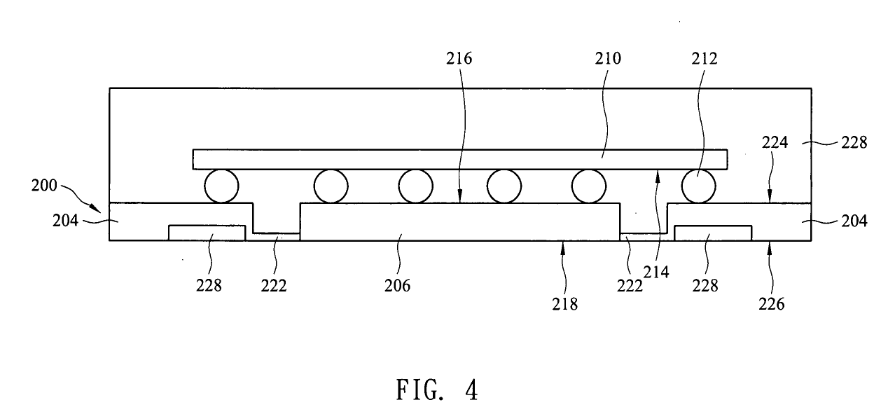

Reference is made to FIGS. 2 through 4, of which FIG. 2 illustrates a top view of a lead frame in accordance with a preferred embodiment of the present invention, and FIGS. 3 and 4 respectively illustrate cross-sectional views of two chip package structures in accordance with a preferred embodiment of the present invention. The chip package structure of the present invention includes a carrier, such as a lead frame 200, which is mainly used to carry a chip 210, such as shown in FIGS. 3 and 4. In the chip package structure of the present invention, the lead frame 200 is mainly composed of a heat-sinking pad 206 and a plurality of pins 202, wherein the pins 202 are connected by a connection frame 208 at the outer edge of the lead frame 200. In the present invention, the heat-sinking pad 206 is a chip carrier having a heat-sinking function, and the heat-sinking pad 206 includes a carrying surface 216 and a heat-sinking surface 218, wherein the carrying surface 216 and the heat-sinking surface 218 are at opposite sides of the heat-sinking pad 206. Generally, the heat-sinking pad 206 is located in the central part of the lead frame 200, and the pins 202 extend from the connection frame 208 at the outer edge of the lead frame 200 to the central part of the lead frame 200 and surround the heat-sinking pad 206. That is, one end of each pin 202 is connected with the connection frame 208, and the other end of each pin 202 is at the periphery of the heat-sinking pad 206, such that the pins 202 are typically at the edge of the lead frame 200, such as shown in FIG. 2.

There are at least two supporting bars 204 among these pins 202, wherein one end of each supporting bar is connected with the connection frame 208, and the other end of each supporting bar extends toward the heat-sinking pad 206 and is connected with the heat-sinking pad 206, such as to support the heat-sinking pad 206. The required number of the supporting bars 204 is at least two for stably supporting the heat-sinking pad 206, and is four preferably. It is noteworthy that the lead frame 200 includes four supporting bars extending at four corners of the lead frame 200 in the present embodiment; however, the amount of the supporting bars 204 is not limited to the aforementioned description but is simply as many as necessary to support the 206 firmly. Furthermore, the supporting bars 204 do not need to be deposed at the corners of the lead frame 200 in the present invention but can be selected from the pins 202 in the appropriate locations according to the design requirement.

In one preferred embodiment of the present invention, each supporting bar 204 includes a connection part 220 that extends from an upper surface 224 of the supporting bar 204 and is connected to a side of the heat-sinking pad 206, such that an upper surface of the connection part 220 is adjacent to the carrying surface 216, such as shown in FIG. 3. In another embodiment of the present invention, each supporting bar 204 similarly includes a connection part 222, which extends from a lower surface of the supporting bar 204 and is connected to a side of the heat-sinking pad 206, wherein a lower surface of the connection part 222 is adjacent to the heat-sinking surface 218, such as shown in FIG. 4.

Referring to FIGS. 3 and 4 simultaneously, a plurality of bonding bumps 212 are disposed on predetermined locations of a surface 214 of the chip 210, wherein the bonding bumps 212 include signal bonding bumps, ground bumps or supply bumps. The chip 210 is deposed in the central part of the lead frame 200 and can be attached to the lead frame 200 by a flip chip method with the bonding bumps 212 of the chip 210. The greater portion of the chip 210 is on the carrying surface 216 of the heat-sinking pad 206, and the smaller portion of the chip 210 covers the end of each pin 202 adjacent to the heat-sinking pad 206. Parts of the bonding bumps 212 are adhered to the carrying surface 216 of the heat-sinking pad 206, and the other parts of the bonding bumps 212 are respectively adhered to the upper surfaces 224 of all pins 202 including supporting bars 204. One feature of the present invention is that in the present chip package structure, all pins 202 including supporting bars 204 are respectively connected to the bonding bumps 212 on the chip 210 to electrically connect all pins 202 with the chip 210.

In the present invention, the supporting bars 204 may be electrically connected with signal bonding bumps of the bonding bumps 212 for controlling typical functions of the chip 210 and may also be electrically connected with ground bumps and/or supply bumps. While the supporting bar 204 is electrically connected with the signal bonding bump of the bonding bumps 212 for controlling the chip 210, the connection part 220 (FIG. 3) or the connection part 222 (FIG. 4) of the supporting bar 204 needs to be cut off after the sequential flip chip step to disconnect the electrical connection between the support bar 204 and the heat-sinking pad 206. However, while the supporting bar 204 is electrically connected with the ground bump and/or supply bump of the bonding bumps 212, the connection part 220 (FIG. 3) or the connection part 222 (FIG. 4) of the supporting bar 204 does not need to be cut off after the sequential flip chip step. An encapsulant 228 covers the chip 210, a portion of the heat-sinking pad 206, and a portion of each pin 202, thus filling up the space between the chip 210, the heat-sinking pad 206, and the pins 202 such that the heat-sinking surface 218 of the heat-sinking pad 206 and a lower surface 226 of each pin 202 are exposed, as shown in FIGS. 3 and 4. The exposure of the heat-sinking surface 218 of the heat-sinking pad 206 can facilitate dissipating heat from the chip 210.

In the chip package structure of the present invention, all pins 202 including the supporting bars 204 are respectively connected to the bonding bumps 212 on the chip 210, and each of the supporting bars 204 is connected to any one of the signal bonding bump, the ground bump and the supply bump. Thus, the supporting bars 204, as the other pins 202, are used as normal connection pins, each of which has its function. As a result, the supporting bars 204 neither waste the space of the lead frame 200 nor hamper the design flexibility of the lead frame 200.

In the fabrication of the chip package structure of the present invention, the lead frame 200 of FIG. 2 is provided, and then a chip 210 is provided, wherein a plurality of bonding bumps 212 are deposed on the surface 214 of the chip 210, and the bonding bumps 212 include signal bonding bumps, ground bumps, and supply bumps. A flip chip step is performed to attach the chip 210 in the central part of the lead frame 200 by the bonding bumps 212, wherein the greater portion of the chip 210 is on the carrying surface 216 of the heat-sinking pad 206, and the smaller portion of the chip 210 covers the end of each pin 202 adjacent to the heat-sinking pad 206. Parts of the bonding bumps 212 are adhered to the carrying surface 216 of the heat-sinking pad 206, and the other parts of the bonding bumps 212 are respectively adhered to the upper surfaces 224 of all pins 202 including supporting bars 204, such as shown in FIGS. 3 and 4. The chip 210 is attached to the lead frame 200 by performing, for example, a reflowing step.

The supporting bars 204 may be electrically connected with signal bonding bumps for controlling typical functions of the chip 210, ground bumps, or supply bumps of the bonding bumps 212 on the chip 210. While the supporting bar 204 is electrically connected with the signal bonding bump of the bonding bumps 212, the connection part 220 of the supporting bar 204 extends from the upper surface 224 of the supporting bar 204 and connects to a side of the heat-sinking pad 206 such that the upper surface of the connection part 220 is contiguous to the carrying surface 216 (such as shown in FIG. 3). The connection part 220 of the supporting bar 204 needs to be cut off by, for example, a laser cutting method or an etching method before the sequential molding step, to disconnect the electrical connection between the support bar 204 and the heat-sinking pad 206.

While the supporting bar 204 is electrically connected with the signal bonding bump of the bonding bumps 212 for controlling the chip 210, the connection part 222 of the supporting bar 204 extends from the lower surface 226 of the supporting bar 204 and connects to a side of the heat-sinking pad 206 such that the lower surface of the connection part 222 is contiguous to the heat-sinking surface 218 of the heat-sinking pad 206 (such as shown in FIG. 4). The connection part 222 of the supporting bar 204 may be cut off by, for example, a laser cutting method or an etching method after the sequential molding step, to disconnect the electrical connection between the support bar 204 and the heat-sinking pad 206. While the supporting bar 204 is electrically connected with the ground bump and/or supply bump of the bonding bumps 212, the connection part 220 (FIG. 3) or the connection part 222 (FIG. 4) of the supporting bar 204 does not need to be cut off, and the sequential molding step is performed immediately.

The molding step is performed and the encapsulant 228 is provided to cover the chip 210, a portion of the heat-sinking pad 206 and a portion of each pin 202, and also to fill up the space between the chip 210, the heat-sinking pad 206, and the pins 202; and the heat-sinking surface 218 of the heat-sinking pad 206 and a lower surface 226 of each pin 202 are exposed, such as shown in FIGS. 3 and 4. The exposure of the heat-sinking surface 218 of the heat-sinking pad 206 can facilitate dissipating heat from the chip 210. The chip package structure of the present invention is thus nearly complete.

According to the aforementioned description, one advantage of the present invention is that in the lead frame of the chip package structure, the supporting bars of the heat-sinking pad can be used as normal pins of the lead frame, such that the space of the lead frame can be effectively utilized.

According to the aforementioned description, another advantage of the present invention is that the method for manufacturing a chip package structure uses pins of the lead frame as supporting bars, so that the design limitation of the lead frame can be reduced, thereby facilitating the design flexibility of the lead frame.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A chip package structure, wherein the chip package structure is a quad flat no-lead package structure, and the chip package structure comprises:
a carrier, wherein the carrier is a lead frame, and the carrier comprises:
a heat-sinking pad having a carrying surface;
a plurality of pins; and
at least two supporting bars;
a chip deposed on the carrier, wherein the chip comprises a plurality of bonding bumps and is flipped and connected to the heat-sinking pad, the pins, and the supporting bars of the carrier, wherein the bonding bumps include a plurality of ground bumps and a plurality of supply bumps, and the supporting bars are electrically connected to the ground bumps and/or the supply bumps; and
an encapsulant covering the chip and a portion of the carrier and exposing a portion of each pin, a portion of each supporting bar, and a portion of the heat-sinking pad.

2. The chip package structure according to claim 1, wherein the supporting bars are connected to and support the heat-sinking pad.

3. The chip package structure according to claim 1, wherein each of the supporting bars has a connection part connected to a side of the heat-sinking pad, and an upper surface of the connection part is contiguous to the carrying surface.

4. The chip package structure according to claim 1, wherein the heat-sinking pad has a heat-sinking surface opposite to the carrying surface, and each of the supporting bars includes a connection part connected to a side of the heat-sinking pad, and a lower surface of the connection part is contiguous to the heat-sinking surface.

5. The chip package structure according to claim 1, wherein the supporting bars are respectively deposed at corners of the carrier.

6. The chip package structure according to claim 1, wherein the supporting bars are respectively deposed at an edge of the carrier.

7. A method for manufacturing a chip package structure, comprising:
providing a lead frame, wherein the lead frame comprises:
a heat-sinking pad having a carrying surface for carrying a chip;
a plurality of pins; and
at least two supporting bars for supporting the heat-sinking pad, and the supporting bars are suitable for electrically connecting the chip, wherein the supporting bars are located at regions outside of corner regions of the lead frame;
providing a chip, wherein a surface of the chip comprises a plurality of bonding bumps deposed thereon;
connecting the chip to the lead frame, wherein the step of connecting the chip to the lead frame is performed by a reflowing method to attach the bonding bumps onto the heat-sinking pad, the pins, and the supporting bars, and the chip is electrically connected to the heat-sinking pad, the pins, and the supporting bars by the bonding bumps;
performing a molding step to enclose the chip, a portion of each pin, a portion of each supporting bar, and a portion of the heat-sinking pad, and to expose another portion of each pin, another portion of each supporting bar, and another portion of the heat-sinking pad; and
performing a separation step to disconnect the supporting bars and the heat-sinking pad, wherein the separation step is performed after the molding step.

8. The method for manufacturing a chip package structure according to claim 7, wherein the separation step includes a laser cutting method or an etching method.

9. A method for manufacturing a chip package structure, comprising:
providing a lead frame, wherein the lead frame comprises:
a heat-sinking pad having a carrying surface for carrying a chip;
a plurality of pins; and
at least two supporting bars for supporting the heat-sinking pad, and the supporting bars are suitable for electrically connecting the chip, wherein the supporting bars are located at regions outside of corner regions of the lead frame;
providing a chip, wherein a surface of the chip comprises a plurality of bonding bumps deposed thereon;
connecting the chip to the lead frame, wherein the step of connecting the chip to the lead frame is performed by a reflowing method to attach the bonding bumps onto the heat-sinking pad, the pins, and the supporting bars, and the chip is electrically connected to the heat-sinking pad, the pins, and the supporting bars by the bonding bumps;
performing a separation step to disconnect the supporting bars and the heat-sinking pad, wherein the separation step is performed between the step of connecting the chip to the lead frame and the molding step; and
performing a molding step to enclose the chip, a portion of each pin, a portion of each supporting bar, and a portion of the heat-sinking pad, and to expose another portion of each pin, another portion of each supporting bar, and another portion of the heat-sinking pad.

10. The method for manufacturing a chip package structure according to claim 9, wherein the separation step includes a laser cutting method or an etching method.
